(19) United States
(12) Patent Application Publication
(10) Pub. No.: US 2014/0097457 A1
(43) Pub. Date: Apr. 10, 2014

(54) SEMICONDUCTOR DEVICE

(71) Applicants: CHIA-HUNG WU, TAICHUNG CITY (TW); WEN-YUH JYWE, TAICHUNG CITY (TW); HUNG-TA CHIEN, HSIN-CHU CITY (TW); FU-CHIANG HSU, HSIN-CHU CITY (TW); FANG-HSUAN SU, HSIN-CHU CITY (TW); CHUN-LIN YEH, TAICHUNG CITY (TW)

(72) Inventors: CHIA-HUNG WU, TAICHUNG CITY (TW); WEN-YUH JYWE, TAICHUNG CITY (TW); HUNG-TA CHIEN, HSIN-CHU CITY (TW); FU-CHIANG HSU, HSIN-CHU CITY (TW); FANG-HSUAN SU, HSIN-CHU CITY (TW); CHUN-LIN YEH, TAICHUNG CITY (TW)

(73) Assignees: CORETRONIC CORPORATION, HSIN-CHU CITY (TW); PRECISION MOTION INDUSTRIES INC., TAICHUNG CITY (TW); ALPHA PLUS EPI, INC., TAICHUNG CITY (TW); TYNTEK CORPORATION, HSINCHU CITY (TW); MICROHERTZ TECHNOLOGIES CO., LTD., TAICHUNG CITY (TW)

(21) Appl. No.: 13/936,093

(22) Filed: Jul. 5, 2013

(30) Foreign Application Priority Data
Oct. 9, 2012 (TW) 101137238

(51) Int. Cl. H01L 33/60

(52) U.S. Cl. CPC H01L 33/60
USPC 257/98

(57) ABSTRACT

A semiconductor device includes a substrate and a semiconductor unit. The substrate includes a base and at least one pattern unit. The pattern unit includes a plurality of surrounding members disposed on the base and a central member surrounded by the surrounding members. A geometrical center is collectively defined by the surrounding members, an interval between the central member and the geometrical center is larger than zero. The semiconductor unit is disposed on the substrate and is operating with a current.

### FIELD OF THE INVENTION

The present invention relates to an electronic device, and more particularly to a semiconductor device.

### BACKGROUND OF THE INVENTION

FIG. 1 is a schematic cross-sectional view of a semiconductor light emitting device disclosed in US Patent Application Publication No. 2010264447. The semiconductor light emitting device includes a substrate 11 having a regular recess/protrusion surface structure, an n-type epitaxial layer 12 deposited on the substrate 11, an active layer 13 deposited on the n-type epitaxial layer 12 and a p-type epitaxial layer 14 deposited on the active layer 13. The active layer 13 emits light in response to a current supply. Emitted light may be desirably reflected with the recess/protrusion surface structure of the substrate 11 so as to enhance light extraction efficiency.

However, since all the faces of the regular recess/protrusion surface structure are neat, most of the reflected light is distributed in a direction perpendicular to the surface of the substrate 11. As a result, the light intensity is much higher in the normal direction of the substrate surface than in any other direction. Therefore, the conventional semiconductor light emitting device is not suitable for the use in products requiring wide-field light emission, such as an emergency exit sign and so on.

### SUMMARY OF THE INVENTION

The present invention provides a semiconductor device having a wide range of light-emitting angles.

The semiconductor device of the present invention includes a substrate and a semiconductor unit. The substrate includes a base and at least one pattern unit disposed on the base. The pattern unit includes a plurality of surrounding members disposed on the base and a central member surrounded by the surrounding members. A geometrical center is collectively defined by the surrounding members, an interval between the central member and the geometrical center is larger than zero. The semiconductor unit is disposed on the substrate and is capable of operating with a current.

Since the central member of the substrate is deviated from the geometrical center of the surrounding members, the semiconductor device of the present invention enables the light emitted by the semiconductor unit to be reflected in multiple angles, so that the light may have a wide range of light-emitting angles.

### BRIEF DESCRIPTION OF THE DRAWINGS

The present invention will become more readily apparent to those ordinarily skilled in the art after reviewing the following detailed description and accompanying drawings, in which:

FIG. 1 is a schematic cross-sectional view of a semiconductor light emitting device according to prior art;

FIG. 2 is a schematic top view illustrating a pattern unit of a semiconductor device according to a first embodiment of the present invention;

FIG. 3 is a schematic cross-sectional view of a semiconductor device which comprises the pattern unit as depicted in FIG. 2;

FIG. 4 is a schematic top view illustrating a pattern unit of a semiconductor device according to a second embodiment of the present invention;

FIG. 5 is a schematic cross-sectional view of a semiconductor device which comprises the pattern unit as depicted in FIG. 4;

FIG. 6 is a schematic top view illustrating a combination of pattern units adapted to be used in a semiconductor device according to a third embodiment of the present invention;

FIG. 7 is a schematic cross-sectional view of a semiconductor device which comprises the pattern units as depicted in FIG. 6;

FIG. 8 is a schematic cross-sectional view of a semiconductor device according to a fourth embodiment of the present invention;

FIG. 9 is a schematic cross-sectional view of a semiconductor device according to a fifth embodiment of the present invention;

FIG. 10 is a schematic diagram of a pattern unit according to a sixth embodiment of the present invention.

FIG. 11 is a schematic cross-sectional view of a semiconductor device which comprises the pattern unit as depicted in FIG. 10.

FIG. 12 is a cross-sectional schematic view of a semiconductor device according to a seventh embodiment of the present invention.

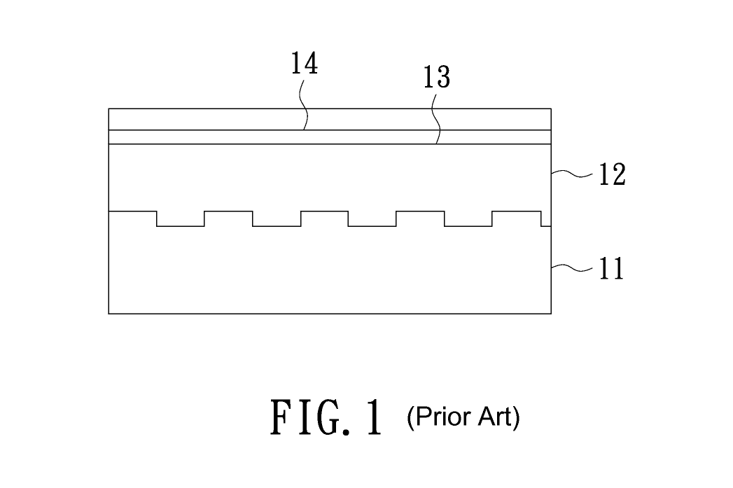

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

Before the present invention is described in detail, it should be noted that, in the following description, similar components are indicated with the same labels.

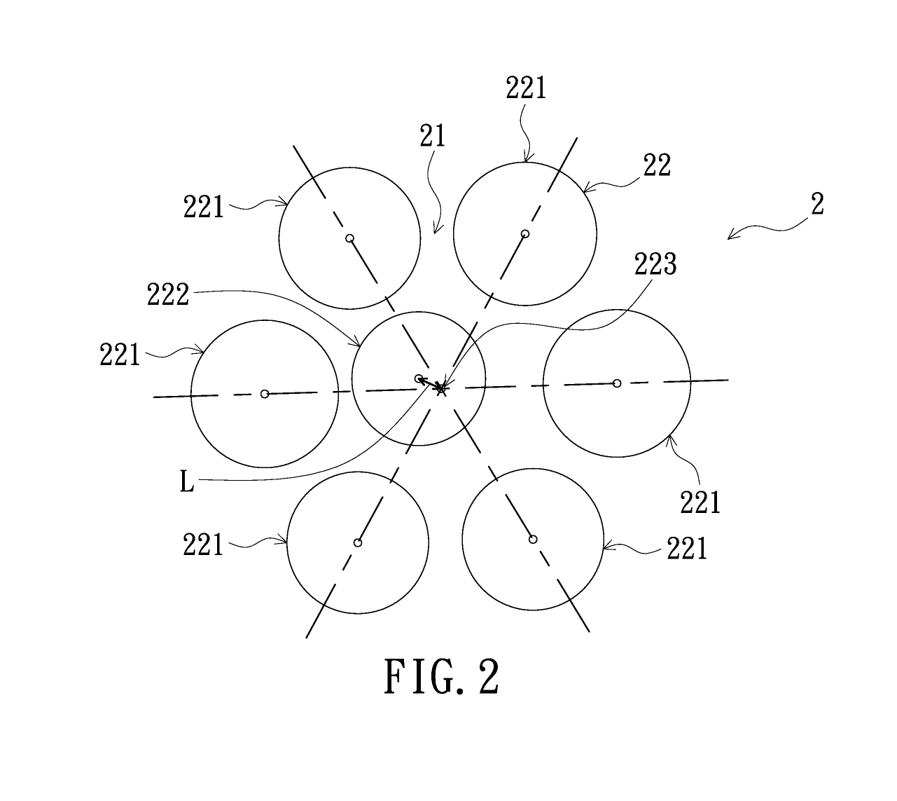

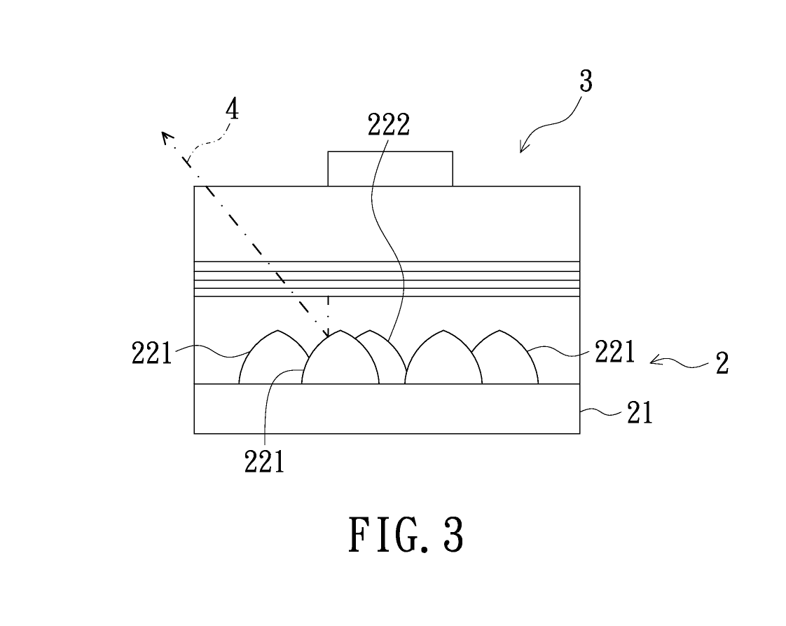

Referring to FIG. 2 and FIG. 3, a semiconductor device according to a first embodiment of the present invention includes a substrate 2 and a semiconductor unit 3.

The substrate 2 includes a base 21 and a pattern unit 22 disposed on the base 21. The pattern unit 22 includes a plurality of surrounding members 221 disposed on the base 21 and a central member 222 surrounded by the surrounding members 221. A geometrical center 223 is collectively defined by the surrounding members 221. An interval L between the central member 222 and the geometrical center 223 is larger than zero. In particular, the interval L is a distance between the central point of the central member 222 and the geometrical center 223.

The semiconductor unit 3 is disposed on the substrate 2 and is capable of emitting light when supplied with a current. In this embodiment, III-V group elements-based semiconductors are used as the main materials to manufacture the semiconductor unit 3. GaAs is taken as an example in this embodiment. Furthermore, in this embodiment, a GaAs substrate is exemplified as the substrate 2. Alternatively, an InP substrate or any other substrate suitable for growth of GaAs may also be used. Since the substrate 2 is made of an electrically conductive material, the semiconductor device may be configured as a vertical structure.

By having the central member 222 of the substrate 2 deviated from the geometrical center 223 of the surrounding members 221, light 4 emitted by the semiconductor unit 3 may be reflected along multiple angles so as to have a wide range of emitting angles. Additionally, the stress accumulated inside the material (for example, in the epitaxial layer of LED) may be relieved due to the deviation of the central member 222 from the geometrical center 223. Therefore, the stress accumulated inside the material is reduced so as to extend service life of the semiconductor device.

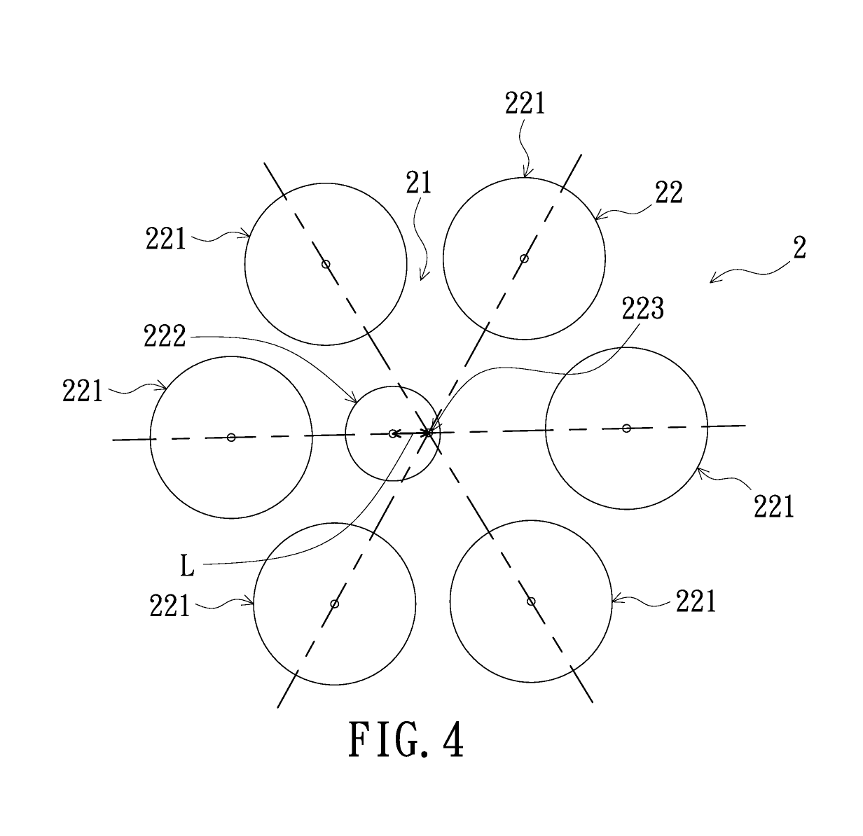

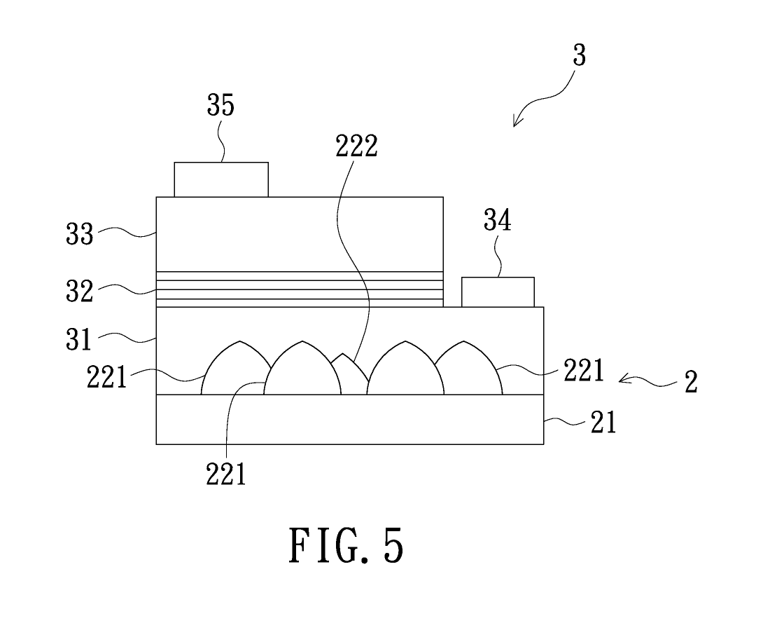

Referring to FIG. 4 and FIG. 5, a semiconductor device according to a second embodiment of the present invention is shown. This embodiment is similar to the first embodiment except that the semiconductor unit 3 is made of a nitride-based material, in particular, a GaN-based compound or composition, such as InGaN, AlGaN, AlInGaN and so on. Alternatively, the materials are not limited to those described above, and any other material which may promote light emission efficiency and/or reduce the stress inside the material may also be used instead of or added to the above-mentioned material.

The material of the substrate 2 may be selected from the group consisting of Al₂O₃, Si, SiC, GaN, AlN, SiO₂ and a combination thereof. An Al₂O₃ substrate is taken as an example of the substrate 2 in this embodiment.

The semiconductor unit 3 includes a first polarity member 31 disposed on the substrate 2, a quantum well member 32 disposed on the first polarity member 31, a second polarity member 33 disposed on the quantum well member 32 and having a polarity opposite to the polarity of the first polarity member 31, a first electrode 34 disposed on the first polarity member 31, and a second electrode 35 disposed on the second polarity member 33. A wavelength of the light emitted by the semiconductor unit 3 is ranged from 365 nanometers to 600 nanometers.

When a diameter of the surrounding members 221 and the central member 222 is 600 nanometers, desirable scattering effect for light of short wavelength may be achieved with the interval L being 100 nanometers. Specifically, the interval L is set to be 100 nanometers in this embodiment.

When a diameter of the surrounding members 221 and the central member 222 is 200 nanometers, desirable scattering effect for light of short wavelength may be achieved with the interval L being 20 nanometers. Therefore, for different sizes of the surrounding members 221 and the central member 222, the intervals ranged from 0 to 2000 nanometers are preferred, but the range is not limited to the exemplified one. Furthermore, the surrounding members 221 of the substrate 2 have a first size, and the central member 222 has a second size, in this embodiment, wherein the first size is larger than the second size. Alternatively, the first size may be smaller than the second size according to the practical requirement, and the relationship between the first size and the second size is not limited to the exemplified one.

In this embodiment, by specifically setting the interval L, the relatively short wavelength light emitted by GaN-based semiconductor unit may be effectively scattered. Moreover, the stress inside the material (for example, in the epitaxial layer of LED) may be relieved due to the deviation of the central member 222 from the geometrical center 223. Therefore, the stress accumulated inside the material is reduced so as to extend service life of the semiconductor device.

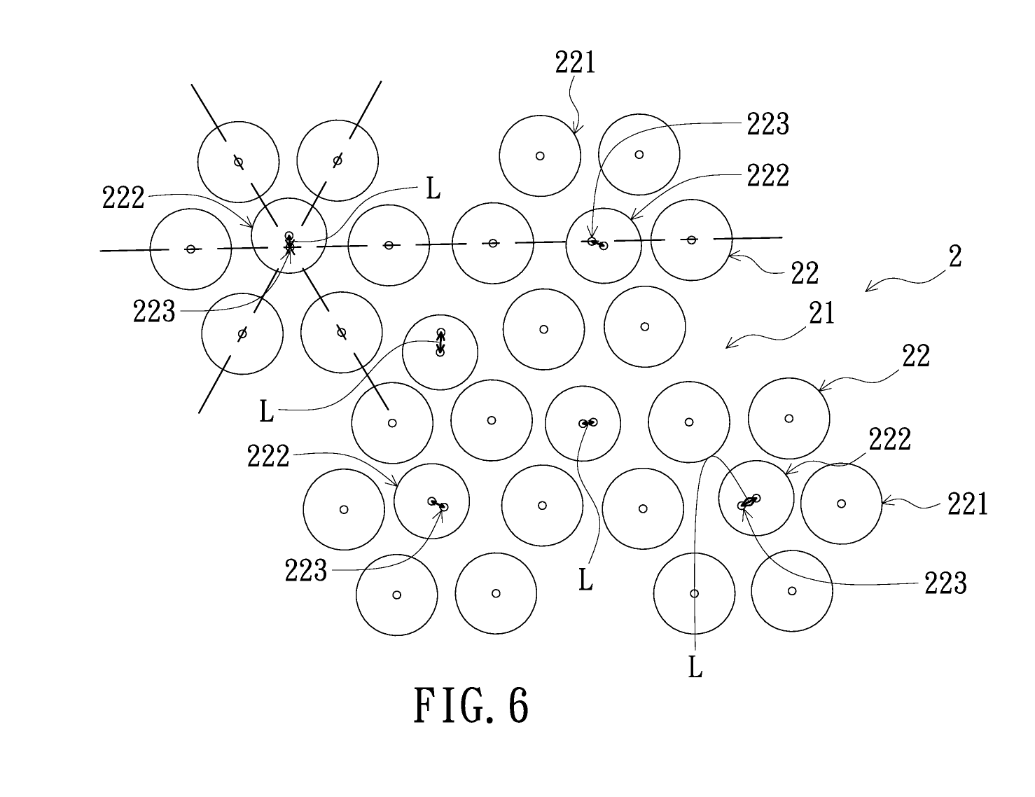

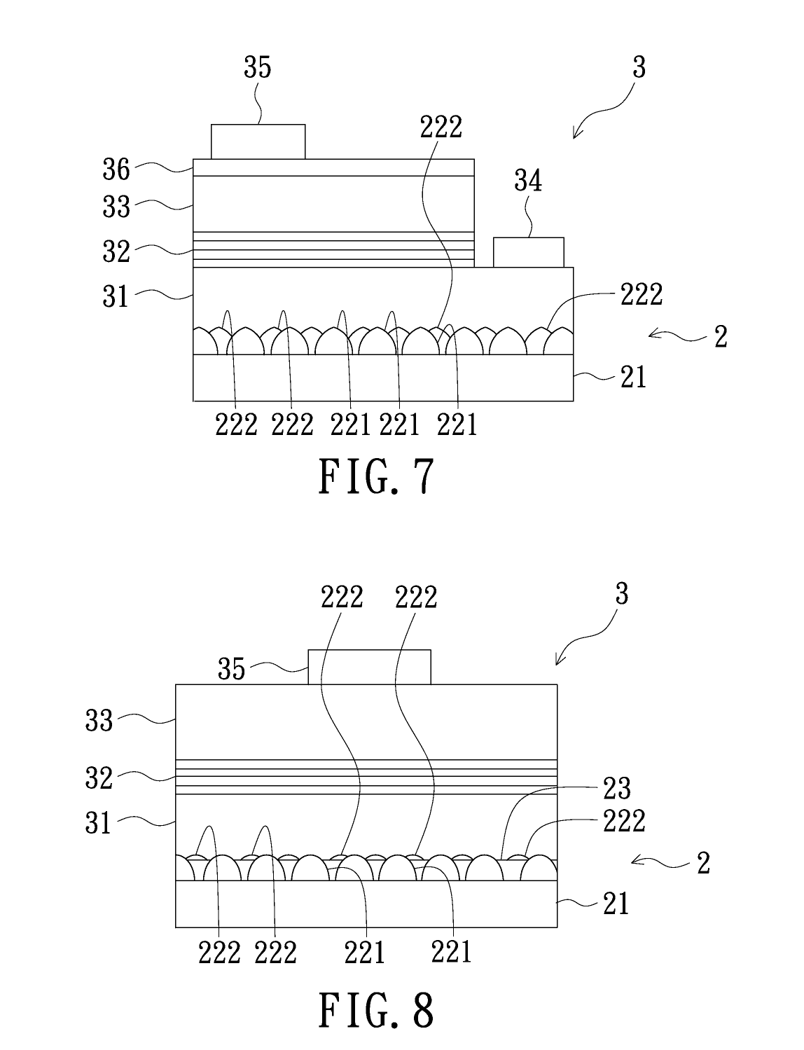

Referring to FIG. 6 and FIG. 7, a semiconductor device according to a third embodiment of the present invention is shown. This embodiment is similar to the second embodiment except that the substrate 2 includes a plurality of pattern units 22, and adjacent pattern units share surrounding members 221. Moreover, the intervals L between the central member 222 and the corresponding geometrical center 223 of every adjacent two pattern units 22 are different, and the displacement directions between the central member 222 and the corresponding geometrical center 223 of every adjacent two pattern units 22 are also different. Each of the intervals L is produced under the deliberate control, and the intervals L range from 0 to 2000 nanometers.

The semiconductor unit 3 includes a first polarity member 31 disposed on the substrate 2, a quantum well member 32 disposed on the first polarity member 31, a second polarity member 33 disposed on the quantum well member 32 and having a polarity opposite to the polarity of the first polarity member 31, and a first electrode 34 disposed on the first polarity member 31, a transparent conductive layer 36 disposed on the second polarity member 33, and a second electrode 35 disposed on the transparent conductive layer 36.

In this embodiment, the transparent conductive layer 36 is made of ITO (indium tin oxide). Alternatively, ZnO, AZO (aluminum-doped zinc oxide), IZO (indium zinc oxide), or any other suitable conductive and light-transmissive material may be used to replace ITO. The material of the transparent conductive layer 36 is not limited to the exemplified one.

In this embodiment, the first polarity member 31 is formed of an N-type semiconductor, and the second polarity member 33 is formed of a P-type semiconductor. Alternatively, the polarities of the first polarity member 31 and the second polarity member 33 may be exchanged. The types of polarities of the first polarity member 31 and the second polarity member 33 are not limited to the exemplified ones.

In this embodiment, the semiconductor unit 3 is made of nitride base, in particular, an AlGaN-based compound or composition. Examples include AlN, InGaN, GaN, AlInGaN and so on. Alternatively, any other material which may promote light emission efficiency or reduce the stress inside the material may be used or added. In this embodiment, a wavelength of the light emitted by the semiconductor unit 3 is ranged from 360 nanometers to 480 nanometers.

In this embodiment, the substrate 2 is may be a sapphire substrate. Alternatively, a Si substrate, a GaN substrate, a SiC substrate or any other substrate suitable for growth of a GaN-based semiconductor unit may also be used, and the types of the substrate are not limited to the exemplified ones.

Moreover, in this embodiment, the thickness of the substrate 2 is ranged from 10 micrometers to 500 micrometers. It is to be noted that, heat dissipation of the semiconductor unit 3 could be affected by the thickness of the substrate 2. The thickness of the substrate 2 configured for epitaxy is about 500 micrometers, and the substrate 2 may be polished to a suitable thickness. The thinner the substrate 2 is, the higher the breaking probability, and the more difficult the subsequent process is. In this embodiment, the thickness of the substrate 2 is set to be 150 micrometers, but the thickness may be adjusted according to the requirements of the semiconductor unit 3 and the overall design. The thickness of the substrate 2 should not be limited to the exemplified one.

According to this embodiment, since the pattern units 22 include the central members 222 facing to different directions and involving different intervals L, the light may be evenly scattered. Furthermore, concentration of the light along the axial direction may be prevented, and the scattering angle range of the light may be broadened. Moreover, the stress inside the material may be relieved due to deviation of the central member 222 from the geometrical center 223. Therefore, the stress accumulated inside the material is reduced so as to extend service life of the semiconductor device.

Referring to FIG. 8, a semiconductor device according to a fourth embodiment of the present invention is shown. This embodiment is similar to the third embodiment except that the substrate 2 further includes a distributed Bragg reflector 23 disposed on the base 21. The surrounding members 221 and the central member 222 are not entirely covered by the distributed Bragg reflector 23. Instead, the surrounding members 221 and the central member 222 partially protrude out of the distributed Bragg reflector 23.

The semiconductor unit 3 is a light emitting diode with a vertical structure. The semiconductor unit 3 includes a first polarity member 31 disposed on the substrate 2, a quantum well member 32 disposed on the first polarity member 31, a second polarity member 33 disposed on the quantum well member 32 and having a polarity opposite to the polarity of the first polarity member 31, and a second electrode 35 disposed on the second polarity member 33.

In this embodiment, the substrate 2 is exemplified as a Si substrate. Alternatively, a GaN substrate, a SiC substrate, a sapphire substrate or any other substrate suitable for growth of GaN-based semiconductor may also be used. The types of the substrate 2 should not be limited to the exemplified ones.

In this embodiment, the distributed Bragg reflector (DBR) 23 is alternately stacked with SiO₂ and TiO₂. The distributed Bragg reflector 23 formed by stacking two kinds of material, which are different in refractive indices. The larger the difference between the two refractive indexes is, the fewer layers the distributed Bragg reflector 23 needs for desirable reflectivity. Basically, transparent conductive material and light transmitting material are adapted to manufacture the distributed Bragg reflector 23. Except SiO₂ and TiO₂ exemplified above, the material for forming the distributed Bragg reflector 23 may also be selected form ZnO, ITO, AZO, IZO, Al and/or any other material with similar properties in this aspect. The thickness and material of each layer of the distributed Bragg reflector 23 are designed according to wavebands of the light to be emitted by the semiconductor unit 3. The material of distributed Bragg reflector 23 should not be limited to the exemplified ones.

In this embodiment, during the epitaxial growth of the first polarity member 31, the epitaxial layer may grow over the surrounding members 221 and the central member 222 protruding out of the distributed Bragg reflector 23. When the semiconductor unit 3 emits light with current supply, the light may be effectively reflected by the distributed Bragg reflector 23 so as to enhance light extraction efficiency. Moreover, the stress inside the material may be relieved due to deviation of the central member 222 from the geometrical center 223. Therefore, the stress accumulated inside the material may be reduced so as to extend service life of the semiconductor device.

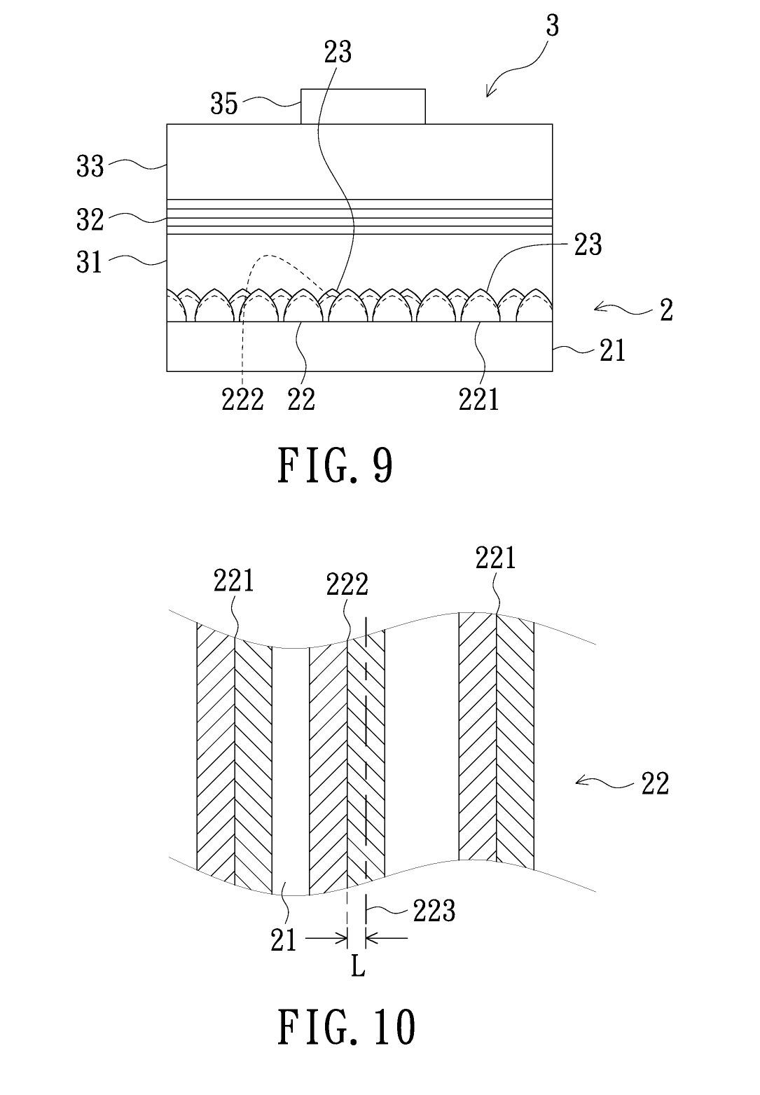

Referring to FIG. 9, a semiconductor device according to a fifth embodiment of the present invention is shown. This embodiment is similar to the fourth embodiment except that the semiconductor unit 3 is a light emitting diode with a vertical structure, and the distributed Bragg reflector 23 is only disposed on the surrounding members 221 and the central member 222.

In this embodiment, the substrate 2 is exemplified as a Si substrate. Alternatively, a GaN substrate, a SiC substrate, a sapphire substrate or any other substrate suitable for growth of the GaN-based semiconductor unit may also be used. The types of the substrate 2 are not to be limited to the exemplified ones.

In this embodiment, the distributed Bragg reflector (DBR) 23 is alternately stacked with SiO₂ and TiO₂. The distributed Bragg reflector 23 formed by stacking two kinds of material, which are different in refractive indices. The larger the difference between the two refractive indexes is, the fewer layers the distributed Bragg reflector 23 needs for desirable reflectivity. Basically, transparent conductive material and light transmitting material are adapted to manufacture the distributed Bragg reflector 23. Except SiO₂ and TiO₂ exemplified above, the material for forming the distributed Bragg reflector 23 may also be selected form ZnO, ITO, AZO, IZO, Al, Ag, Ti, Au and/or any other material with similar properties in this aspect. The thickness and material of each layer of the distributed Bragg reflector 23 are designed according to wavebands of the light to be emitted by the semiconductor unit 3. The material of distributed Bragg reflector 23 should not be limited to the exemplified ones.

In this embodiment, during the epitaxial growth of the first polarity member 31, the epitaxial layer may grow on the base 21 except for the distributed Bragg reflector 23. When the semiconductor unit 3 emits light with current supply, the light may be effectively reflected by the distributed Bragg reflector 23 so as to enhance light extraction efficiency. Moreover, the stress inside the material may be relieved due to the deviation of the central member 222 from the geometrical center 223. Therefore, the stress accumulated inside the material may be reduced so as to extend service life of the semiconductor device.

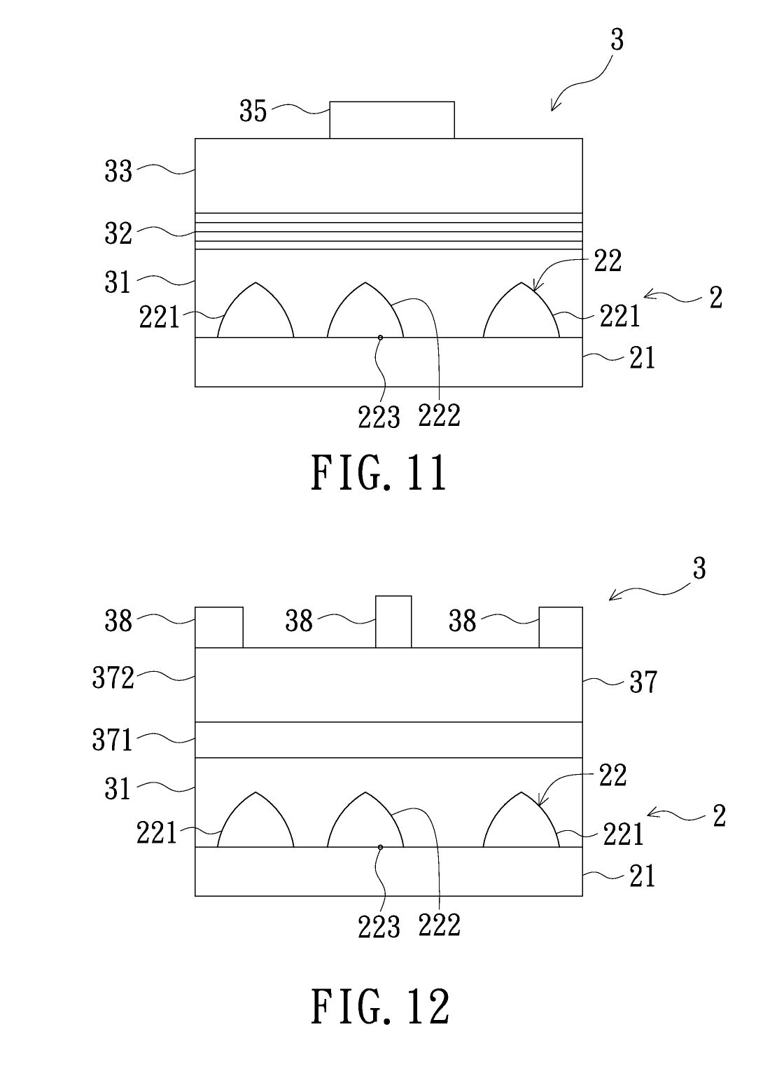

Referring to FIG. 10 and FIG. 11, a semiconductor device according to a sixth embodiment of the present invention is shown. This embodiment is similar to the second embodiment, except that, in this embodiment, the geometrical center 223 of the substrate 2 is a line, the surrounding members 221 and the central member 222 are line-shaped, and the interval L is a distance between the central member 222 and the geometrical center 223.

The semiconductor unit 3 is a light emitting diode with a vertical structure. The substrate 2 is exemplified as a Si substrate. Alternatively, a Si substrate, a SiC substrate, a sapphire substrate or any other substrate suitable for growth of the GaN-based semiconductor unit may also be used, the types of the substrate 2 are not limited by the present embodiment.

According to this embodiment, not only light may be sufficiently reflected by the line-shaped surrounding members 221 and central member 222, but also the manufacturing cost may be reduced. Moreover, the stress inside the material may be relieved due to the deviation of the central member 222 from the geometrical center 223. Therefore, the stress accumulated inside the material may be reduced so as to extend service life of the semiconductor device.

Referring to FIG. 12, a semiconductor device according to a seventh embodiment of the present invention is shown. This embodiment is similar to the second embodiment except that the semiconductor unit 3 is a high electro mobility transistor (HEMT) having two-dimensional electron gas (2 DEG). The semiconductor unit 3 includes a first polarity member 31 disposed on the substrate 2, a high-speed conductive layer 37 disposed on the first polarity member 31 and capable of forming the two-dimensional electron gas, and three electrodes 38 disposed on the high-speed conductive layer 37. In this embodiment, the high-speed conductive layer 37 includes a GaN layer 371 and an AlGaN layer 372. The two-dimensional electron gas is formed on a surface in contact with the GaN layer 371 and the AlGaN layer 372.

In this embodiment, the high electro mobility transistor is not configured for emitting light. Furthermore, since the pattern unit 22 of the substrate 2 may promote epitaxy quality, and the stress inside the material may be relieved due to the deviation of the central member 222 from the geometrical center 223. Therefore, the stress accumulated inside the material is reduced so as to extend service life of the semiconductor device.

In summary, since the central member 222 of the substrate 2 is deviated from the geometrical center 223 of the surrounding members 221, the semiconductor device of the present invention the light emitted by the semiconductor unit 3 may be reflected along multiple angles, so that the light has a wide range of emitting angles.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A semiconductor device, comprising:
a substrate comprising a base and at least one pattern unit disposed on the base, the pattern unit comprising a plurality of surrounding members disposed on the base and a central member surrounded by the surrounding members, wherein a geometrical center is collectively defined by the surrounding members, an interval between the central member and the geometrical center is larger than zero; and
a semiconductor unit disposed on the substrate, wherein the semiconductor unit is capable of operating with a current.

2. The semiconductor device according to claim 1, wherein the semiconductor unit emits light when provided with a current.

3. The semiconductor device according to claim 1, wherein the interval between the central member of the pattern unit and the geometrical center is smaller than 2000 nanometers.

4. The semiconductor device according to claim 1, wherein the substrate further comprises a distributed Bragg reflector disposed on the surrounding members and the central member.

5. The semiconductor device according to claim 1, wherein the substrate further comprises a distributed Bragg reflector disposed on the base and partially covering the surrounding members and the central member.

6. The semiconductor device according to claim 1, wherein the surrounding members of the substrate has a first size, and the central member has a second size different from the first size.

7. The semiconductor device according to claim 1, wherein the substrate comprises a plurality of pattern units, and adjacent two of the pattern units share a portion of the surrounding members.

8. The semiconductor device according to claim 1, wherein the substrate comprises a plurality of pattern units, intervals between the central member and the corresponding geometrical center of adjacent two of the pattern units are different, and the displacement directions between the central members and the corresponding geometrical centers of the adjacent two pattern units are also different.

9. The semiconductor device according to claim 1, wherein a material of the substrate includes at least one selected from the group consisting of Al₂O₃, Si, SiC, GaN, AlN, GaAs, InP and SiO₂.

10. The semiconductor device according to claim 1, wherein a material of the semiconductor unit includes at least one selected from the group consisting of GaN, AlN, AlGaN, InGaN and GaAs.
